(19) United States
(12) Patent Application Publication
(10) Pub. No.: US 2013/0192879 A1
(43) Pub. Date: Aug. 1, 2013

(54) MULTILAYER PRINTED WIRING BOARD

(71) Applicants: Haruhiko MORITA, Ogaki-shi (JP); Ryojiro TOMINAGA, Ogaki-shi (JP); Atsushi ISHIDA, Ogaki-shi (JP); Satoshi WATANABE, Ogaki-shi (JP)

(72) Inventors: Haruhiko MORITA, Ogaki-shi (JP); Ryojiro TOMINAGA, Ogaki-shi (JP); Atsushi ISHIDA, Ogaki-shi (JP); Satoshi WATANABE, Ogaki-shi (JP)

(73) Assignee: IBIDEN Co., Ltd., Ogaki-shi (JP)

(21) Appl. No.: 13/560,239

(22) Filed: Jul. 27, 2012

Related U.S. Application Data
(60) Provisional application No. 61/538,027, filed on Sep. 22, 2011.

(51) Int. Cl. H05K 1/11; H05K 3/10

(52) U.S. Cl. CPC H05K 1/115; H05K 3/10
USPC 174/251; 29/846

(57) ABSTRACT

A multilayer printed wiring board has a core substrate including first insulation layers, first conductive patterns formed on the first insulation layers, and first via conductors formed through the first insulation layers and connecting the first conductive patterns, and a buildup layer formed on the core substrate and including second insulation layers, second conductive patterns formed on the second insulation layers, and second via conductors formed through the second insulation layers and connecting the second conductive patterns. Each of the first insulation layers includes an inorganic reinforcing fiber material, each of the second insulation layers does not include an inorganic reinforcing fiber material, and the core substrate includes an inductor having the first conductive patterns and the first via conductors.

### CROSS-REFERENCE TO RELATED APPLICATIONS

The present application is based on and claims the benefit of priority to U.S. application Ser. No. 61/538,027, filed Sep. 22, 2011, the entire contents of which are incorporated herein by reference.

### BACKGROUND OF THE INVENTION

1. Field of the Invention

The present invention relates to a multilayer printed wiring board where a buildup layer formed on a core substrate has insulation layers, conductive patterns on the insulation layers, and via conductors that are formed in the insulation layers and connect the conductive patterns to each other.

2. Discussion of the Background

In Japanese Laid-Open Patent Publication No. 2009-16504, an inductor is formed in a wiring board by electrically connecting conductive patterns in different layers. The entire contents of this publication are incorporated herein by reference.

### SUMMARY OF THE INVENTION

According to one aspect of the present invention, a multilayer printed wiring board has a core substrate including first insulation layers, first conductive patterns formed on the first insulation layers, and first via conductors formed through the first insulation layers and connecting the first conductive patterns, and a buildup layer formed on the core substrate and including second insulation layers, second conductive patterns formed on the second insulation layers, and second via conductors formed through the second insulation layers and connecting the second conductive patterns. Each of the first insulation layers includes an inorganic reinforcing fiber material, each of the second insulation layers does not include an inorganic reinforcing fiber material, and the core substrate includes an inductor having the first conductive patterns and the first via conductors.

According to another aspect of the present invention, a method for manufacturing a multilayer printed wiring board includes forming a core substrate including first insulation layers, first conductive patterns formed on the first insulation layers, and first via conductors formed through the first insulation layers and connecting the first conductive patterns, and forming on the core substrate a buildup layer including second insulation layers, second conductive patterns formed on the second insulation layers, and second via conductors formed through the second insulation layers and connecting the second conductive patterns. The forming of the core substrate includes forming each of the first insulation layers having an inorganic reinforcing fiber material, the forming of the buildup layer includes forming each of the second insulation layers not having an inorganic reinforcing fiber material, and the forming of the core substrate includes forming an inductor having the first conductive patterns and the first via conductors.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a multilayer printed wiring board according to a first embodiment of the present invention;

FIG. 2 is a view showing the structure of conductive patterns of inductor according to the first embodiment;

FIGS. 3(A)-(B) are views schematically showing positions of second via conductors in a buildup layer;

FIGS. 4(A)-(B) are views schematically showing positions of second via conductors in a buildup layer;

FIGS. 5(A)-(G) are views of steps showing a method for manufacturing a multilayer printed wiring board according to the first embodiment;

FIGS. 6(A)-(F) are views of steps showing a method for manufacturing a multilayer printed wiring board according to the first embodiment;

FIGS. 7(A)-(D) are views of steps showing a method for manufacturing a multilayer printed wiring board according to the first embodiment;

FIGS. 8(A)-(D) are views of steps showing a method for manufacturing a multilayer printed wiring board according to the first embodiment;

FIGS. 9(A)-(C) are views of steps showing a method for manufacturing a multilayer printed wiring board according to the first embodiment; and

FIG. 10 is a cross-sectional view of a multilayer printed wiring board according to a second embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

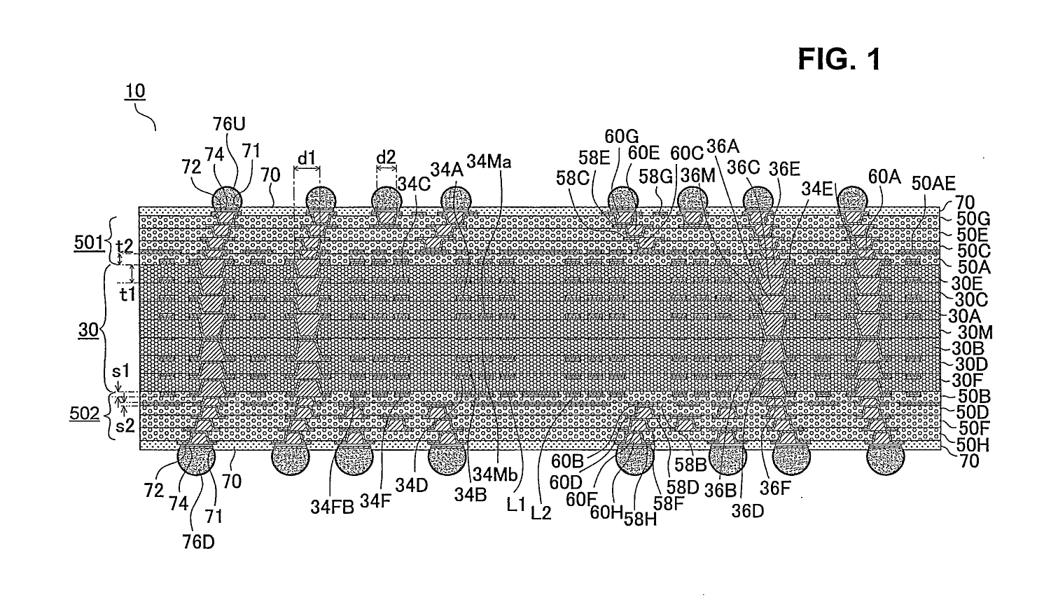

FIG. 1 is a cross-sectional view of a multilayer printed wiring board according to a first embodiment. Multilayer printed wiring board 10 has core substrate 30. Core substrate 30 includes multiple first insulation layers (30M, 30A, 30B, 30C, 30D, 30E, 30F), first conductive patterns (34Ma, 34Mb, 34A, 34B, 34C, 34D, 34E, 34F) on the first insulation layers, and first via conductors (36M, 36A, 36B, 36C, 36D, 36E, 36F) formed in the first insulation layers and connecting the first conductive patterns to each other. The first insulation layers of core substrate 30 contain inorganic reinforcing fiber material. Such inorganic reinforcing fiber material is not limited to a specific type, and glass cloth, glass non-woven fabric, aramid cloth, aramid non-woven fabric and the like, for example, may be used. In addition, there are eight layers of first conductive patterns in the present embodiment to form core substrate 30, but the number of layers is not limited specifically as long as required inductance is obtained in the later-described inductor.

Among the first insulation layers of core substrate 30, on an upper surface of first insulation layer (30M) positioned in the center of a thickness direction, first conductive pattern (34Ma) is formed, and on the opposing lower surface of first insulation layer (30M), first conductive pattern (34Mb) is formed. First via conductor (36M) is formed in first insulation layer (30M), and first conductive pattern (34Ma) and first conductive pattern (34Mb) are connected by first via conductor (36M).

First insulation layers (30A, 30C, 30E) are laminated in that order on the upper surface of first insulation layer (30M). First conductive patterns (34A, 34C, 34E) are formed respectively on first insulation layers (30A, 30C, 30E). Then, first conductive pattern (34A) and first conductive pattern (34Ma) are connected by first via conductor (36A), first conductive pattern (34A) and first conductive pattern (34C) are connected by first via conductor (36C), and first conductive pattern (34C) and first conductive pattern (34E) are connected by first via conductor (36E).

Meanwhile, first insulation layers (30B, 30D, 30F) are laminated in that order on the lower surface of first insulation layer (30M). First conductive patterns (34B, 34D, 34F) are formed respectively on first insulation layers (30B, 30D, 30F). Then, first conductive pattern (34B) and first conductive pattern (34Mb) are connected by first via conductor (36B), first conductive pattern (34B) and first conductive pattern (34D) are connected by first via conductor (36D), and first conductive pattern (34D) and first conductive pattern (34F) are connected by first via conductor (36F).

Core substrate 30 has a first surface on which a semiconductor element (not shown in the drawings) is to be mounted, and a second surface opposite the first surface. On the first surface and second surface of core substrate 30, buildup layers (501, 502) are respectively formed, having second insulation layers, second conductive patterns on the second insulation layers, and second via conductors that are formed in the second insulation layers and connect the second conductive patterns to each other.

The second insulation layers of buildup layers (501, 502) do not contain inorganic reinforcing fiber material. Second conductive pattern (58A) is formed on second insulation layer (50A) of buildup layer 501 formed on the first surface of core substrate 30. Second conductive pattern (58A) and first conductive pattern (34E) are connected by second via conductor (60A). Second insulation layers (50C, 50E, 50G) are laminated in that order on second insulation layer (50A) and second conductive pattern (58A). Second conductive patterns (58C, 58E, 58G) are respectively formed on second insulation layers (50C, 50E, 50G). Then, vertically adjacent second conductive patterns are connected by second via conductors (60C, 60E, 60G) formed in their respective second insulation layers.

Meanwhile, second conductive pattern (58B) is formed on second insulation layer (50B) of buildup layer 502 formed on the second surface of core substrate 30. Second conductive pattern (58B) and first conductive pattern (34F) are connected by second via conductor (60B). Second insulation layers (50D, 50F, 50H) are laminated in that order on second insulation layer (50B) and second conductive pattern (58B). Second conductive patterns (58D, 58F, 58H) are respectively formed on second insulation layers (50D, 50F, 50H). Then, vertically adjacent second conductive patterns are connected by second via conductors (60D, 60F, 60H) formed in their respective second insulation layers.

Solder-resist layer 70 having opening 71 is formed on outermost interlayer resin insulation layer (50G) on the upper-surface side. Solder bump (76U) for connection with a semiconductor element is formed in opening 71. Solder-resist layer 70 having opening 71 is formed on outermost interlayer resin insulation layer (50H) on the lower-surface side. Solder bump (76D) for connection with an external substrate such as a motherboard is formed in opening 71.

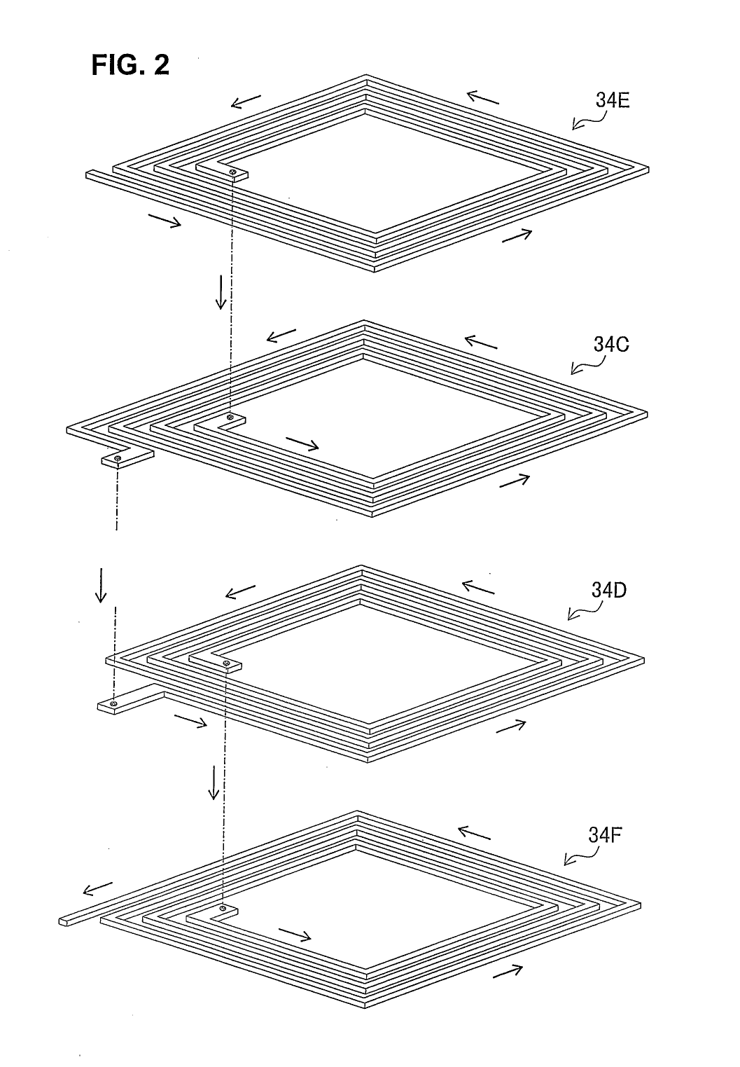

Inductors are formed in core substrate 30. As shown in FIG. 2, an inductor of the present embodiment is made up of spiral first conductive pattern groups formed on the upper surfaces of their respective first insulation layers, and of first via conductors connecting the vertically adjacent spiral first conductive pattern groups. In FIG. 2, first conductive pattern group (34F) on the lowermost layer, first conductive pattern group (34D) on its upper layer, first conductive pattern group (34E) on the uppermost layer, and first conductive pattern group (34C) on its lower layer, are shown among the first conductive pattern groups of the inductor, and the rest of the first conductive pattern groups are omitted.

In the present embodiment, there are at least a pair of adjacent inductors (L1, L2). Such pair of inductors (L1, L2) are electrically connected. Accordingly, voltage converted at a switching portion in a semiconductor element is smoothed through inductors (L1, L2) and a capacitor (not shown in the drawings).

The design of the conductive patterns of inductors (L1, L2) is not limited specifically. The number of inductors is not limited specifically, either.

As shown in FIG. 1, plane layers are respectively formed on first insulation layers (30M, 30A, 30B, 30C, 30D, 30E, 30F) of core substrate 30. Such plane layers work as power source or ground. Each plane layer has a recessed portion in a location where first conductive patterns of inductors (L1, L2) are formed. Accordingly, inductors (L1, L2) are separated from the plane layers in a planar direction, making it easier to achieve required inductance.

First via conductors positioned around inductors (L1, L2) are stacked straight in a thickness direction of core substrate 30. “Being stacked straight” means at least parts of first via conductors adjacent vertically in a thickness direction overlap in a planar direction. If such first via conductors function as a power-source line, the power-source line is shortened, suppressing the loss of voltage to be supplied for a semiconductor element as much as possible.

In the present embodiment, inductors (L1, L2) are positioned directly under the region where a semiconductor element is mounted (the region where bumps (76U) are formed). In such a case, it is easier to supply voltage for the semiconductor element without incurring loss.

In a multilayer printed wiring board of the present embodiment, inorganic reinforcing fiber material is contained in first insulation layers (30M, 30A, 30B, 30C, 30D, 30E, 30F) positioned between vertically adjacent conductive patterns among conductive patterns (34E, 34C, 34A, 34Ma, 34Mb, 34B, 34D, 34F) of the inductors. Therefore, thermal contraction of the first insulation layers tends to be suppressed by highly rigid inorganic reinforcing fiber material. As a result, even when thermal history affects a wiring board during the manufacturing process or reliability testing, for example, warping is thought to be suppressed in the wiring board.

Inductors (L1, L2) are formed in core substrate 30 of a multilayer printed wiring board in the present embodiment. If inductors (L1, L2) are formed in a buildup layer only on either the first surface or the second surface of core substrate 30, the difference increases between the conductor volume in upper buildup layer 501 and the conductor volume in lower buildup layer 502. In such a case, the amounts of thermal contraction from thermal history affecting the wiring board will be different, and warping tends to occur. However, according to the structure of the present embodiment, since inductors (L1, L2) are formed in core substrate 30, it is easier to maintain the symmetry of the upper and lower buildup layers, and it is thought that warping seldom occurs.

In a multilayer printed wiring board of the present embodiment, electrical connection between the upper and lower surfaces of core substrate 30 is secured by via conductors (36E, 36C, 36A, 36M, 36B, 36D, 36F) formed respectively in multiple first insulation layers (30E, 30C, 30A, 30M, 30B, 30D, 30F). Therefore, the ratio of the depth to the opening of a via conductor (aspect ratio) is smaller than that of a penetrating hole with the same thickness which penetrates through the core substrate. Accordingly, even if the diameter of the via conductor openings is small, the flow of a plating solution is excellent when plating is filled in the via conductors. As a result, voids seldom occur, enhancing the reliability of each via conductor. Connection reliability is improved between the upper and lower surfaces of the core substrate. By suppressing voids from occurring in the via conductors of the inductors, the quality of the inductors (Q factors) can be raised.

Diameter (d1) of the first via conductors in core substrate 30 is set greater than diameter (d2) of the second via conductors in buildup layers (501, 502). For example, diameter (d1) of first via conductors in core substrate 30 is 80 μm, and diameter (d2) of the second via conductors in buildup layers is 50 μm. Namely, by increasing the diameter of the first via conductors of the inductors in core substrate 30, the quality of the inductors (Q factors) can become even higher.

In a multilayer printed wiring board of the present embodiment, thickness (s1) of the first conductive patterns of inductors (L1, L2) is set greater than thickness (s2) of second conductive patterns (58B) of buildup layers (501, 502). For example, thickness (s1) of the first conductive patterns of core substrate 30 is 20˜40 μm, and thickness (s2) of the second conductive patterns of the buildup layers is 10˜18 μm.

By increasing the thickness of the first conductive patterns of inductors (L1, L2), the quality of the inductors is improved. Moreover, core substrate 30 becomes rigid. On the other hand, by reducing the relative thickness of the second conductive patterns of buildup layers (501, 502), fine pitches of the conductive patterns in buildup layers (501, 502) are achieved, enabling the wiring board to be multilayered while suppressing the thickness of the entire wiring board.

In a multilayer printed wiring board of the present embodiment, thickness (t1) of first insulation layers (30E, 30C, 30A, 30M, 30B, 30D, 30F) is set greater than thickness (t2) of second insulation layers (50G, 50E, 50C, 50A, 50B, 50D, 50F, 50H) in buildup layers (501, 502). For example, the thickness of the first insulation layers is approximately 60 μm, and the thickness of the second insulation layers is approximately 40 μm. By increasing the thickness of multiple first insulation layers of core substrate 30, the rigidity of core substrate 30 is secured. Moreover, the relative depth of the first via conductors of inductors (L1, L2) becomes greater, and it is easier to secure inductance. On the other hand, by reducing the relative thickness of the second insulation layers, fine pitches of conductive patterns in the buildup layers are achieved, enabling the wiring board to be multilayered while suppressing its entire thickness.

In a multilayer printed wiring board of the present embodiment, among the first via conductors in core substrate 30, first via conductors (36E, 36C, 36A, 36M, 36B, 36D, 36F) which do not form inductors (L1, L2) are stacked straight in a thickness direction. Accordingly, power-source lines or signal lines may be shortened. In addition, by stacking first via conductors, the rigidity of core substrate 30 is secured.

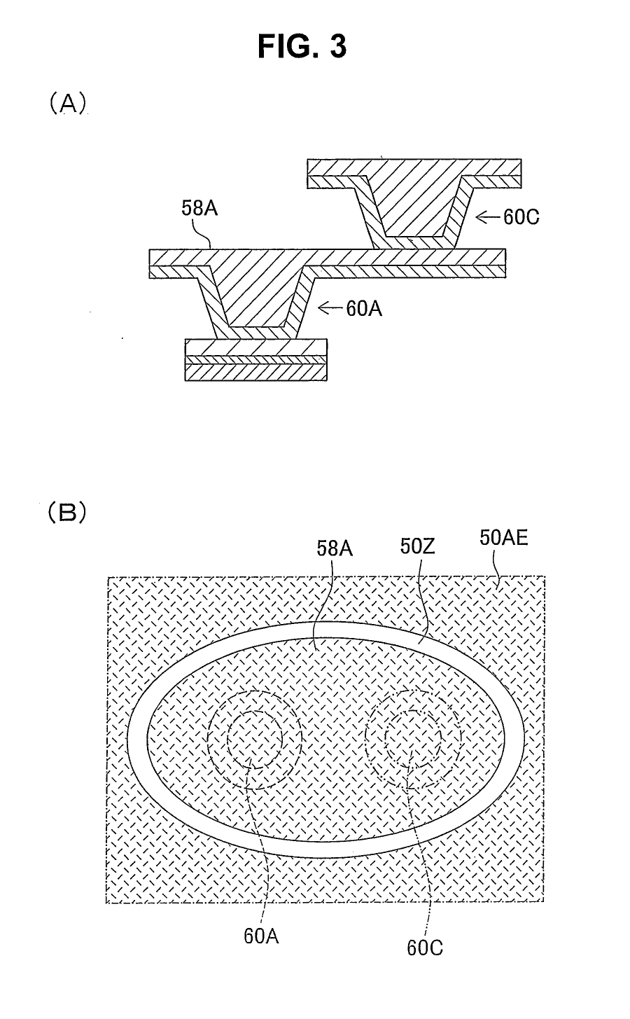

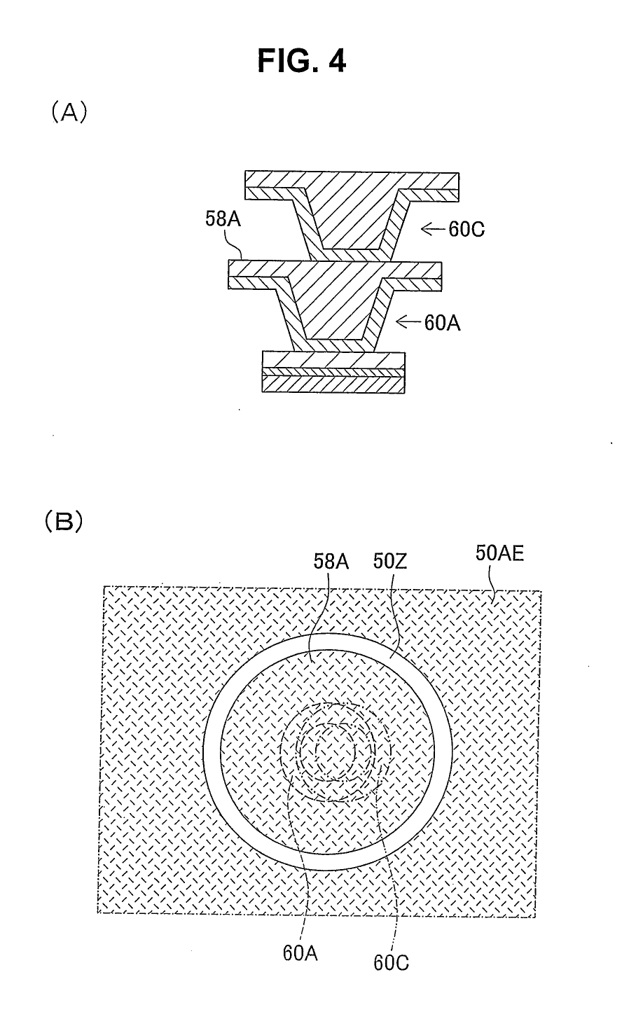

Also, in the present embodiment, multiple second via conductors, which connect uppermost first conductive pattern (34E) of inductors (L1, L2) and second conductive pattern (58G) positioned on the uppermost layer of buildup layer (501), are stacked straight. “Being stacked straight” means situations where at least parts of the second via conductors adjacent vertically in a thickness direction overlap in a planar direction. Here, plane layer (50AE) for power source (ground) is formed on second insulation layer (50A) of buildup layer 501. If vertically adjacent second via conductors (60A, 60C) are shifted in a planar direction as shown in FIG. 3(A), the volume of recessed portion (50Z) to insulate plane layer (50AE) and second conductive pattern (58A) (via land) increases, and the magnetic field tends to leak (see FIG. 3(B)). Accordingly, inductance may be reduced. On the other hand, as shown in FIG. 4(A), if multiple second via conductors (60(A) and 60(C), for example) in a buildup layer are stacked straight, the relative volume of recessed portion (50Z) to insulate plane layer (50AE) and second conductive pattern (58A) (via land) decreases. As a result, the magnetic field is suppressed from leaking, and it is easier to achieve required inductance.

### Method for Manufacturing Multilayer Printed Wiring Board

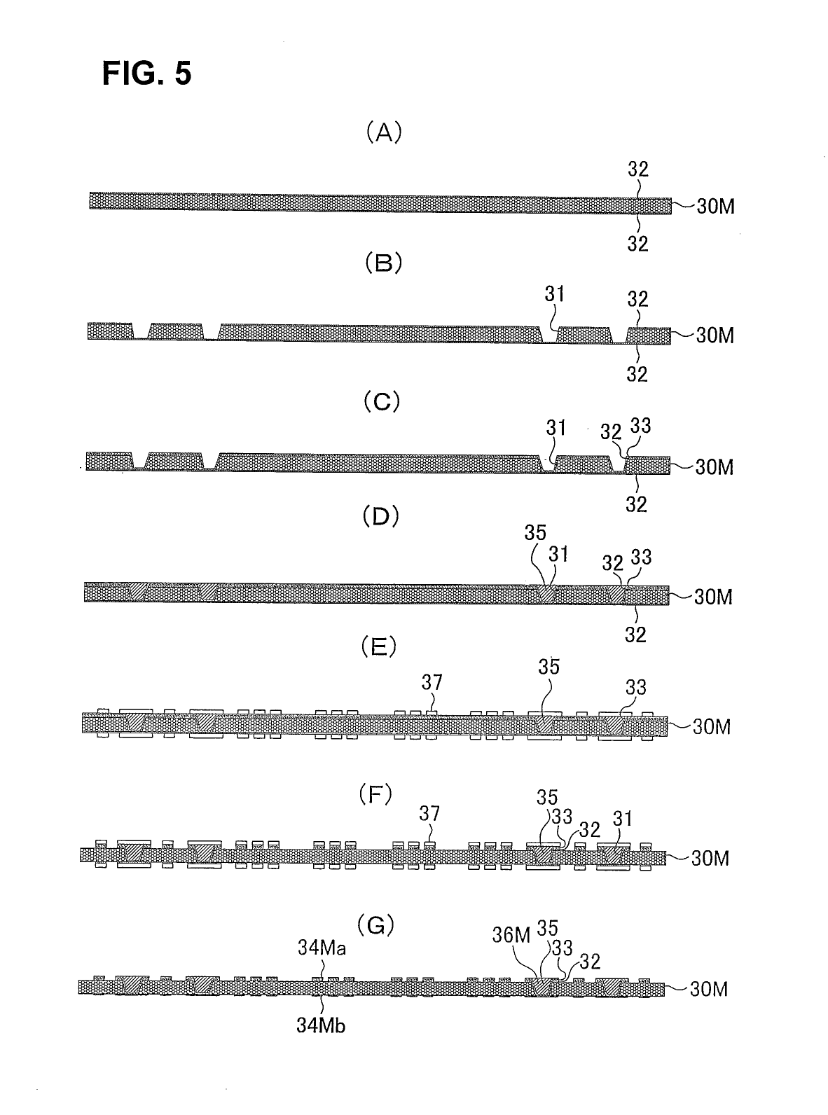

FIGS. 5˜9 show a method for manufacturing a multilayer printed wiring board according to the first embodiment. A double-sided copper-clad laminate (CCL-HL832NSLC) is prepared as a starting material, where copper foils (32, 32) are laminated on both surfaces of insulation layer (30M) which is made of prepreg formed by impregnating glass-cloth core material with epoxy resin (FIG. 5(A)).

Using a laser, via openings 31 are formed to penetrate through copper foil 32 on one side and insulation layer (30M) (FIG. 5(B)). Next, electroless plated film 33 is formed (FIG. 5(C)). Electrolytic plating is performed to form electrolytic plated film 35 on surfaces of the insulation layer and in openings 31 (FIG. 5(D)). Then, etching resists 37 with predetermined patterns are formed on the electrolytic plated films (FIG. 5(E)). Electrolytic plated film 35, electroless plated film 33 and copper foil 32 are removed from the portions where no etching resist is formed (FIG. 5(F)), and the etching resists are removed. Via conductors (36M) made of electroless plated film 33 and electrolytic plated film 35 are formed, and conductive patterns (34Ma, 34Mb) made of electroless plated film 33, electrolytic plated film 35 and copper foil 32 are formed (FIG. 5(G)).

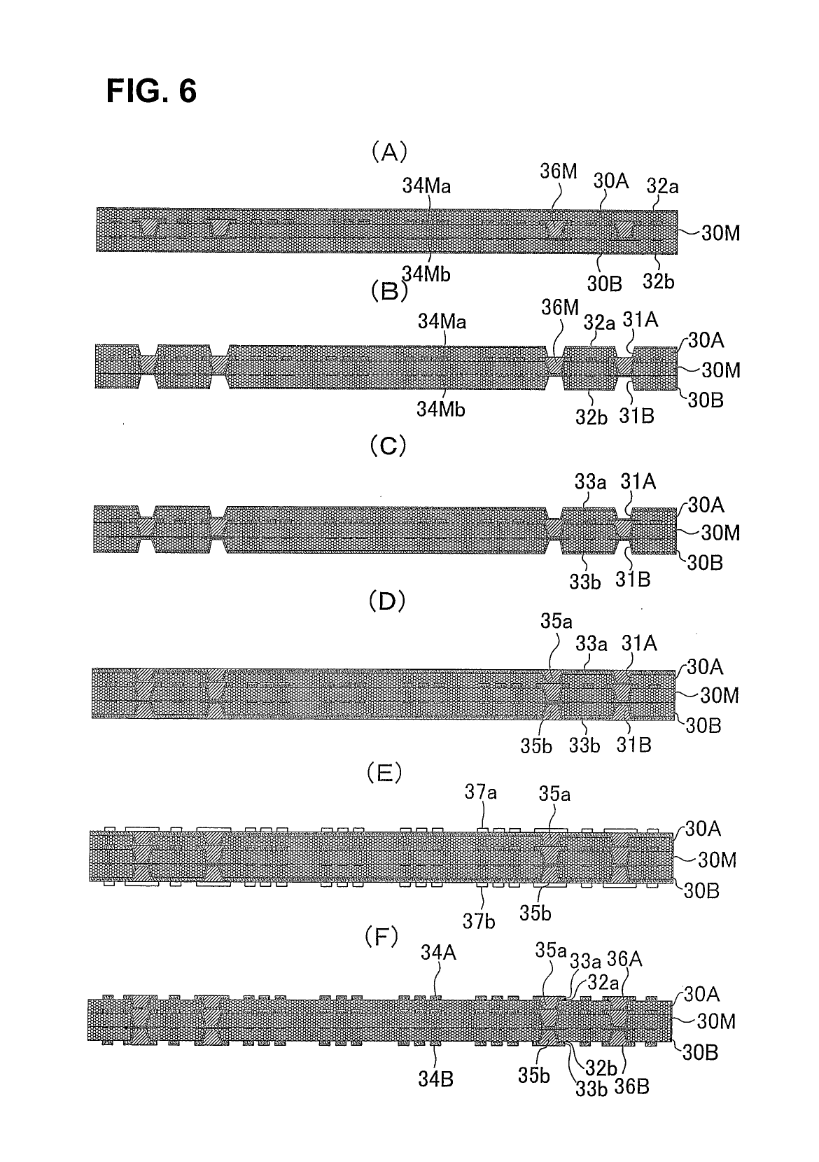

Insulation layer (30A) having copper foil (32a) is laminated on the upper surface of insulation layer (30M), while insulation layer (30B) having copper foil (32b) is laminated on the lower surface of insulation layer (30M) (FIG. 6(A)). The thickness of copper foils (32a, 32b) is reduced by etching, and then by using a laser, via openings (31A) are formed in insulation layer (30A) to reach via conductors (36M), and via openings (31B) are formed in insulation layer (30B) to reach via conductors (36M) (FIG. 6(B)). Electroless plated films (33a, 33b) are formed (FIG. 6(C)). Electrolytic plating is performed to form electrolytic plated films (35a, 35b) on surfaces of insulation layers and in openings (31A, 31B) (FIG. 6(D)). Etching resists (37a, 37b) with predetermined patterns are formed on electrolytic plated films (FIG. 6(E)). After electrolytic plated films (35a, 35b), electroless plated films (33a, 33b) and copper foils (32a, 32b) are removed from the portions where no etching resist is formed, the etching resists are removed. Accordingly, via conductors (36A) made of electroless plated film (33a) and electrolytic plated film (35a) are formed, and conductive pattern (34A) made of electroless plated film (33a), electrolytic plated film (35a) and copper foil (32a) is formed. Moreover, via conductors (36B) made of electroless plated film (33b) and electrolytic plated film (35b) are formed, and conductive pattern (34B) made of electroless plated film (33b), electrolytic plated film (35b) and copper foil (32b) is formed (FIG. 6(F)).

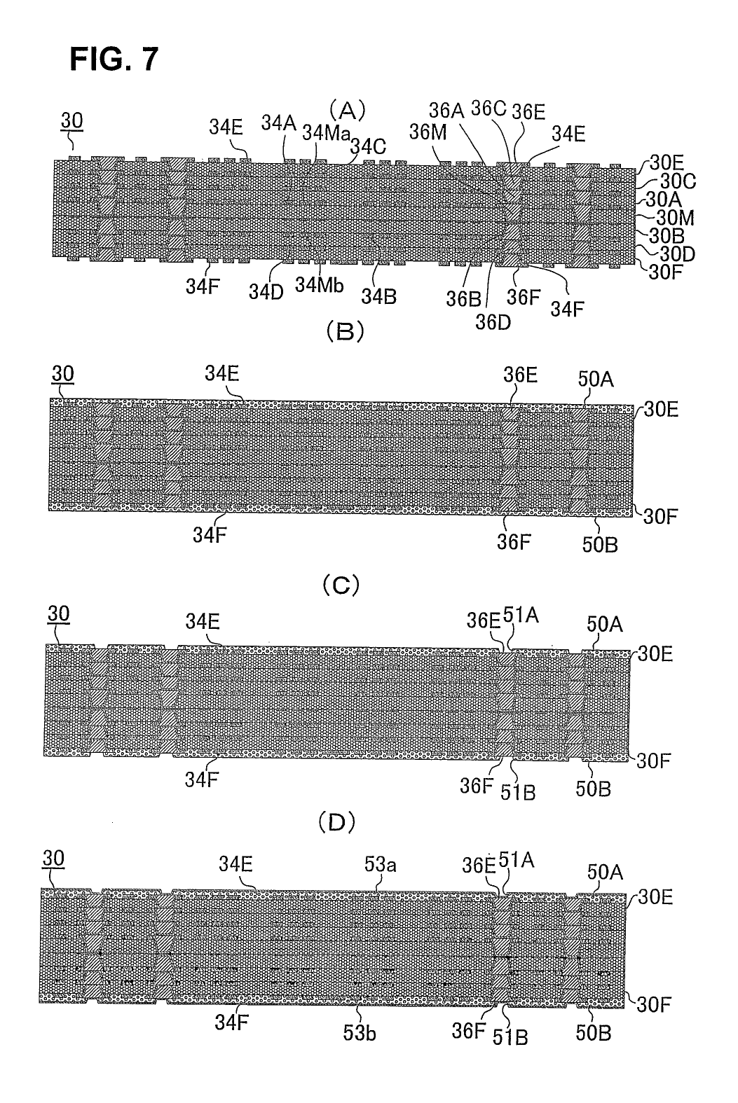

Treatments shown in FIG. 6 are repeated, and insulation layer (30C) having via conductors (36C) and conductive pattern (34C) as well as insulation layer (30D) having via conductors (36D) and conductive pattern (34D) is laminated. Moreover, insulation layer (30E) having via conductors (36E) and conductive pattern (34E) as well as insulation layer (30F) having via conductors (36F) and conductive pattern (34F) is laminated. Accordingly, core substrate 30 of the present embodiment is completed (FIG. 7(A)).

Resin film for interlayer insulation layers that do not contain inorganic reinforcing fiber material (such as glass-cloth core material) is laminated on the first and second surfaces of core substrate 30 and is thermally cured to form interlayer resin insulation layers (50A, 50B) (FIG. 7(B)).

Using a CO2 gas laser, conductive pattern (34E) and openings (51A) that reach via conductors (36E) are formed in interlayer resin insulation layer (50A), and conductive pattern (34F) and openings (51B) that reach via conductors (36F) are formed in interlayer resin insulation layer (50B) (FIG. 7(C)). The laminate is immersed in an oxidation agent such as chromic acid or permanganate so that surfaces of interlayer resin insulation layers (50A, 50B) are roughened (not shown in the drawings).

A catalyst such as palladium is attached to the surfaces of interlayer resin insulation layers (50A, 50B), and the laminate is immersed in an electroless plating solution for 5 to 60 minutes. Accordingly, electroless plated films (53a, 53b) are formed in the range of 0.1˜5 μm (FIG. 7(D)).

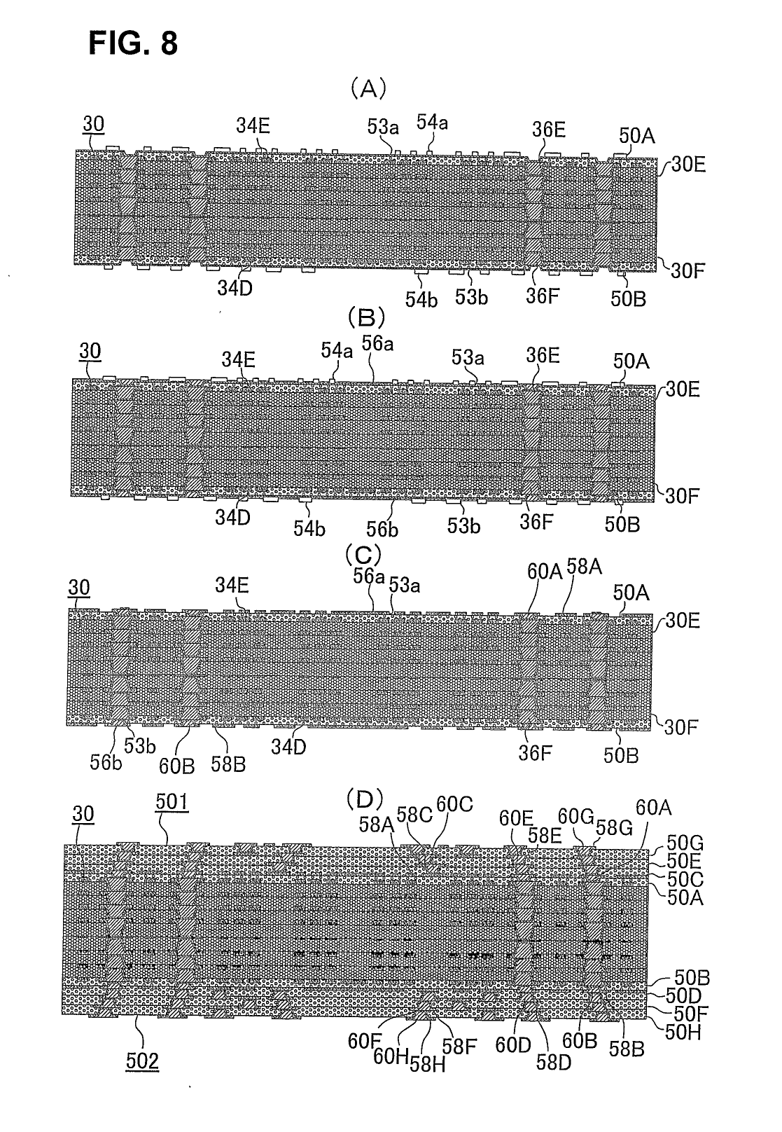

A commercially available photosensitive dry film is pasted on the laminate after the above treatments, and photomask film is placed, exposed to light and developed using sodium carbonate. Accordingly, 15 μm-thick plating resists (54a, 54b) are formed (FIG. 8A)). Electrolytic plating is performed to form 15 pm-thick electrolytic plated films (56a, 56b) (FIG. 8(B)).

After the plating resists are removed by 5% NaOH, electroless plated films (53a, 53b) under the plating resists are dissolved and removed by etching using a mixed solution of nitric acid, sulfuric acid and hydrogen peroxide. Accordingly conductive patterns (58A, 58B) with an approximate thickness of 15 μm and via conductors (60A, 60B) are formed, being made of electroless plated films (53a, 53b) and electrolytic plated films (56a, 56b) (FIG. 8(C)). Surfaces of conductive patterns (58A, 58B) and via conductors (60A, 60B) are roughened using an etching solution containing copper (II) complex and organic acid (not shown in the drawings).

Treatments shown in FIGS. 7(B)-8(C) are repeated to form buildup layer 501 on the first surface of core substrate 30 and buildup layer 502 on the second surface (FIG. 8(D)).

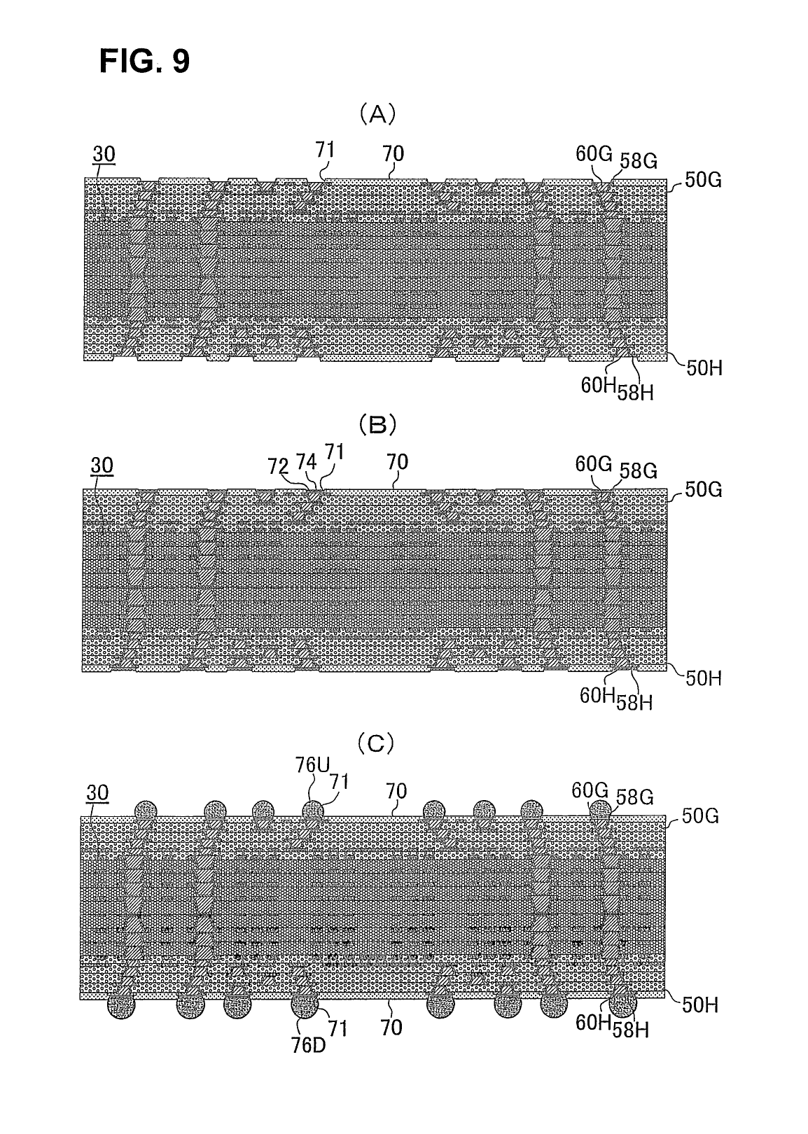

Next, a commercially available solder-resist composition is applied, which is then exposed to light and developed. Accordingly, solder-resist layers 70 having opening portions 71 are formed (FIG. 9(A)).

The laminate is immersed in an electroless nickel plating solution to form nickel-plated layer 72 in opening portions 71. The laminate is further immersed in an electroless gold plating solution to form gold-plated layer 74 on nickel-plated layer 72 (FIG. 9(B)). Instead of nickel-gold layers, nickel-palladium-gold layers may also be formed.

Solder balls are loaded in opening portions 71 and a reflow is conducted to form solder bumps (76U) on the upper-surface side and solder bumps (76D) on the lower-surface side. Accordingly, multilayer printed wiring board 10 is completed (FIG. 9(C) and FIG. 1).

### Second Embodiment

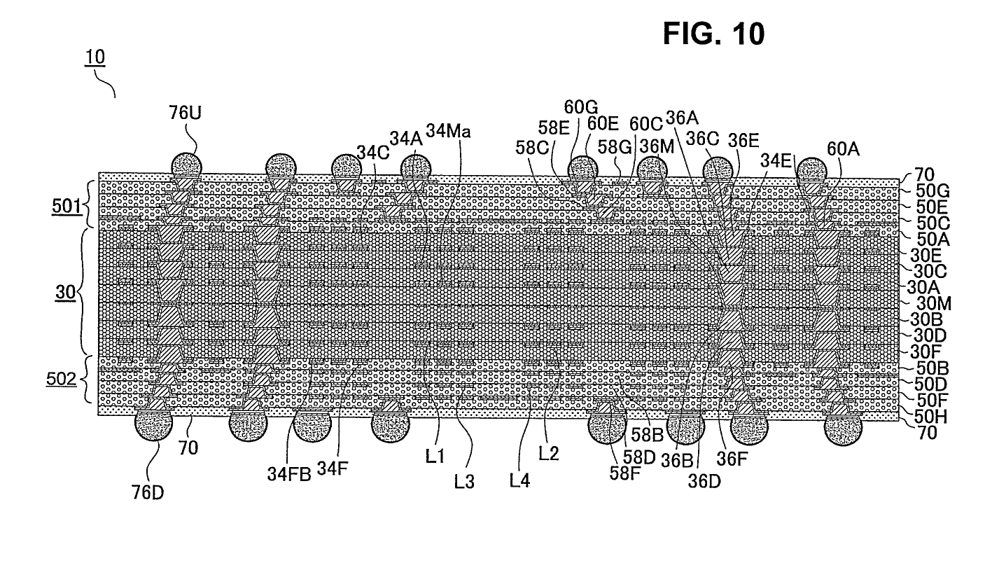

FIG. 10 shows a cross-sectional view of a multilayer printed wiring board according to a second embodiment. In a multilayer printed wiring board according to the second embodiment, inductors (L3, L4) are further formed in a region of buildup layer 502 directly under inductors (L1, L2) formed in core substrate 30. Inductors (L3, L4) are formed using conductive pattern (58B), conductive pattern (58D), conductive pattern (50F), via conductor (60B), via conductor (60D), via conductor (60F) and via conductor (60H). Inductors (L3, L4) formed in buildup layer 502 may be designed the same as inductors (L1, L2) in core substrate 30, or may be designed differently.

Accordingly, since inductors are also formed in buildup layer 502, additional inductance is further secured instead of relying only on the inductance in core substrate 30. Also, differences in conductor volumes in buildup layers (501, 502) can be adjusted on the upper and lower surfaces of core substrate 30, and warping of the wiring board is thought to be reduced.

A multilayer printed wiring board according to an embodiment of the present invention has the following: a core substrate having multiple first insulation layers, first conductive patterns on the first insulation layers, and first via conductors that are formed in the first insulation layers and connect the first conductive patterns to each other; and a buildup layer formed on the core substrate and having second insulation layers that do not contain inorganic reinforcing fiber material, second conductive patterns on the second insulation layers, and second via conductors that are formed in the second insulation layers and connect the second conductive patterns to each other. Such a multilayer printed wiring board has the following technological features: the multiple first insulation layers contain inorganic reinforcing fiber material; and the core substrate includes an inductor formed with the first conductive patterns and the first via conductors.

In a multilayer printed wiring board according to an embodiment of the present invention, the core substrate has multiple first insulation layers, first conductive patterns on the insulation layers, and first via conductors that are formed in the first insulation layers and connect the first conductive patterns to each other. Moreover, an inductor is formed in the core substrate using the first conductive patterns and first via conductors. Such an inductor is formed in the core substrate for the purposes of suppressing the loss of voltage to be supplied for a semiconductor element. Each first insulation layer contains inorganic reinforcing fiber material (such as glass cloth, glass non-woven fabric, aramid cloth, and aramid non-woven fabric). Namely, inorganic reinforcing fiber material for enhancing rigidity is contained in the layers where an inductor is formed. Therefore, thermal contraction of insulation layers tends to be suppressed by the inorganic reinforcing fiber material. As a result, even when thermal history affects a wiring board during a manufacturing process or reliability testing, for example, warping of the wiring board is thought to be suppressed. Furthermore, the height of bumps becomes uniform, improving the mountability of a semiconductor element.

Obviously, numerous modifications and variations of the present invention are possible in light of the above teachings. It is therefore to be understood that within the scope of the appended claims, the invention may be practiced otherwise than as specifically described herein.

What is claimed is:

1. A multilayer printed wiring board, comprising:
a core substrate comprising a plurality of first insulation layers, a plurality of first conductive patterns formed on the first insulation layers, and a plurality of first via conductors formed through the first insulation layers and connecting the first conductive patterns; and
a buildup layer formed on the core substrate and comprising a plurality of second insulation layers, a plurality of second conductive patterns formed on the second insulation layers, and a plurality of second via conductors formed through the second insulation layers and connecting the second conductive patterns,
wherein each of the first insulation layers includes an inorganic reinforcing fiber material, each of the second insulation layers does not include an inorganic reinforcing fiber material, and the core substrate includes an inductor comprising the first conductive patterns and the first via conductors.

2. The multilayer printed wiring board according to claim 1, wherein the plurality of first via conductors includes a plurality of via conductors positioned such that the via conductors are stacked straight in a thickness direction of the core substrate.

3. The multilayer printed wiring board according to claim 1, wherein each of the first conductive patterns has a thickness which is set greater than a thickness of each of the second conductive patterns.

4. The multilayer printed wiring board according to claim 1, wherein each of the first via conductors has a diameter which is set greater than a diameter of each of the second via conductors.

5. The multilayer printed wiring board according to claim 1, wherein each of the first insulation layers has a thickness which is set greater than a thickness of each of the second insulation layers.

6. The multilayer printed wiring board according to claim 1, further comprising a plurality of bumps positioned to mount a semiconductor device, wherein the plurality of bumps is formed on an outermost second conductive pattern positioned on an outermost layer among the second conductive patterns, and the inductor is formed directly under a portion of the buildup layer in which the plurality of bumps is formed.

7. The multilayer printed wiring board according to claim 6, wherein the plurality of first conductive patterns includes an outermost first inductive pattern formed on a surface of the core substrate, and the plurality of second via conductors includes a plurality of via conductors stacked straight between the outermost first conductive pattern and the outermost second conductive pattern such that the outermost first conductive pattern is connected to the outermost second conductive pattern through the via conductors.

8. The multilayer printed wiring board according to claim 1, further comprising a second buildup layer formed on the core substrate on an opposite side of the buildup layer and comprising a second inductor comprising a plurality of conductive patterns and a plurality of via conductors, wherein the second inductor is formed in a portion of the second buildup layer directly under the inductor in the core substrate.

9. The multilayer printed wiring board according to claim 1, wherein the plurality of first conductive patterns of the core substrate forms at least six conductive layers in the core substrate.

10. The multilayer printed wiring board according to claim 1, wherein each of the first conductive patterns has a thickness which is set greater than a thickness of each of the second conductive patterns, and each of the first via conductors has a diameter which is set greater than a diameter of each of the second via conductors.

11. The multilayer printed wiring board according to claim 1, wherein each of the first insulation layers has a thickness which is set greater than a thickness of each of the second insulation layers, each of the first conductive patterns has a thickness which is set greater than a thickness of each of the second conductive patterns, and each of the first via conductors has a diameter which is set greater than a diameter of each of the second via conductors.

12. The multilayer printed wiring board according to claim 1, further comprising a plurality of bumps positioned to mount a semiconductor device, wherein the plurality of bumps is formed on an outermost second conductive pattern positioned on an outermost layer among the second conductive patterns.

13. The multilayer printed wiring board according to claim 12, wherein the plurality of first conductive patterns includes an outermost first inductive pattern formed on a surface of the core substrate, and the plurality of second via conductors includes a plurality of via conductors stacked straight between the outermost first conductive pattern and the outermost second conductive pattern such that the outermost first conductive pattern is connected to the outermost second conductive pattern through the via conductors.

14. The multilayer printed wiring board according to claim 1, further comprising a second buildup layer formed on the core substrate on an opposite side of the buildup layer.

15. A method for manufacturing a multilayer printed wiring board, comprising:
forming a core substrate comprising a plurality of first insulation layers, a plurality of first conductive patterns formed on the first insulation layers, and a plurality of first via conductors formed through the first insulation layers and connecting the first conductive patterns; and
forming on the core substrate a buildup layer comprising a plurality of second insulation layers, a plurality of second conductive patterns formed on the second insulation layers, and a plurality of second via conductors formed through the second insulation layers and connecting the second conductive patterns,
wherein the forming of the core substrate comprises forming each of the first insulation layers comprising an inorganic reinforcing fiber material, the forming of the buildup layer comprises forming each of the second insulation layers not including an inorganic reinforcing fiber material, and the forming of the core substrate comprises forming an inductor comprising the first conductive patterns and the first via conductors.

16. The method for manufacturing a multilayer printed wiring board according to claim 15, wherein the plurality of first conductive patterns is formed with a thickness which is set greater than a thickness of each of the second conductive patterns.

17. The method for manufacturing a multilayer printed wiring board according to claim 15, wherein the plurality of first via conductors is formed with a diameter which is set greater than a diameter of each of the second via conductors.

18. The method for manufacturing a multilayer printed wiring board according to claim 15, wherein the plurality of first insulation layers is formed with a thickness which is set greater than a thickness of each of the second insulation layers.

19. The method for manufacturing a multilayer printed wiring board according to claim 15, further comprising forming a plurality of bumps on an outermost second conductive pattern positioned on an outermost layer among the second conductive patterns such that the plurality of bumps is positioned to mount a semiconductor device, wherein the inductor is formed directly under a portion of the buildup layer in which the plurality of bumps is formed.

20. The method for manufacturing a multilayer printed wiring board according to claim 15, wherein the first conductive patterns are formed by a subtractive method, and the second conductive patterns are formed by a semi-additive method.
